(19) United States
(12) Patent Application Publication
(10) Pub. No.: US 2026/0190777 A1
(43) Pub. Date: Jul. 2, 2026

(54) Display Device

(71) Applicant: LG Display Co., Ltd., Seoul (KR)

(72) Inventors: Inwoo Kwon, Suwon-si (KR); Byoungjin Jeon, Gimpo-si (KR)

(21) Appl. No.: 19/346,332

(22) Filed: Sep. 30, 2025

(30) Foreign Application Priority Data
Dec. 26, 2024 (KR) 10-2024-0196842

(51) Int. Cl. H10K 59/80; H05K 5/03

(52) U.S. Cl. CPC H10K 59/873; H05K 5/03

(57) ABSTRACT

A display device according to an exemplary embodiment of the present disclosure includes a cover window, a display panel disposed below the cover window, a molding member disposed on a side surface of the display panel, and a link assembly which is at least partially disposed between a side of the display panel and the molding member to absorb an impact applied to the display panel.

### CROSS-REFERENCE TO RELATED APPLICATIONS

This application claims the priority of Republic of Korea Patent Application No. 10-2024-0196842 filed on Dec. 26, 2024, in the Korean Intellectual Property Office, the disclosure of which is incorporated herein by reference.

### BACKGROUND

### Field

The present disclosure relates to a display device, and more particularly, to a display device with an improved durability.

### Description of the Related Art

Currently, as it enters a full-scale information era, a field of a display device which visually expresses electrical information signals has been rapidly developed and studies are continued to improve performances of various display devices such as thickness reduction, light weight, and low power consumption.

Among various display devices, a light emitting display device is a self-emitting device so that a separate light source is not necessary, which is different from a liquid crystal display device. Therefore, the light emitting display device may be manufactured to have a light weight and a small thickness. Further, since the light emitting display device is driven at a low voltage so that it is advantageous not only in terms of power consumption, but also in terms of colorreproduction, a response speed, a viewing angle, a contrast ratio (CR). Therefore, it is expected to be utilized in various fields.

In the meantime, in the case of a mobile display device, a display panel may be damaged due to external impacts, which may seriously affect a display quality.

### SUMMARY

An object to be achieved by the present disclosure is to provide a display device which effectively absorbs an impact and a pressure applied from the outside to protect the display panel.

Another object to be achieved by the present disclosure is to provide a display device which minimizes cracks or separation of a display panel caused when impacts are applied to the display device to improve a lifespan.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device includes a cover window, a display panel disposed below the cover window, a molding member disposed on a side surface of the display panel and a link assembly which is at least partially disposed between a side of the display panel and the molding member to absorb an impact applied to the display panel.

Other detailed matters of the exemplary embodiments are included in the detailed description and the drawings.

According to the present disclosure, when external impacts and pressures are applied, crack generation in the display panel can be minimized, thereby minimizing damage to the component of the display device.

According to the present disclosure, a link assembly is disposed between the cover window and the display panel and is configured to elastically support a molding member in response to the deformation of the molding member, thereby effectively protecting the display panel from external impacts or pressures. Accordingly, the durability of the display device is improved and a defect rate is lowered. Further, the lifespan of the display device is improved, maintenance costs are reduced, and user reliability is enhanced, thereby strengthening market competitiveness.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a rear view of a display device according to a first exemplary embodiment of the present disclosure;

FIG. 2 is a cross-sectional view taken along A-A′ of FIG. 1;

FIG. 3 is a partial enlarged perspective view of a display device of FIG. 2;

FIG. 4 is a view illustrating a state in which an external impact is generated, in a display device according to a first exemplary embodiment of the present disclosure;

FIG. 5 is a view illustrating a state which returns to its original state after an external impact is generated, in a display device according to a first exemplary embodiment of the present disclosure;

FIG. 6 is a cross-sectional view of a display device according to a second exemplary embodiment of the present disclosure;

FIG. 7 is a view illustrating a state in which an external impact is generated, in a display device according to a second exemplary embodiment of the present disclosure;

FIG. 8 is a cross-sectional view of a display device according to a third exemplary embodiment of the present disclosure; and

FIG. 9 is a view illustrating a state in which an external impact is generated, in a display device according to a third exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

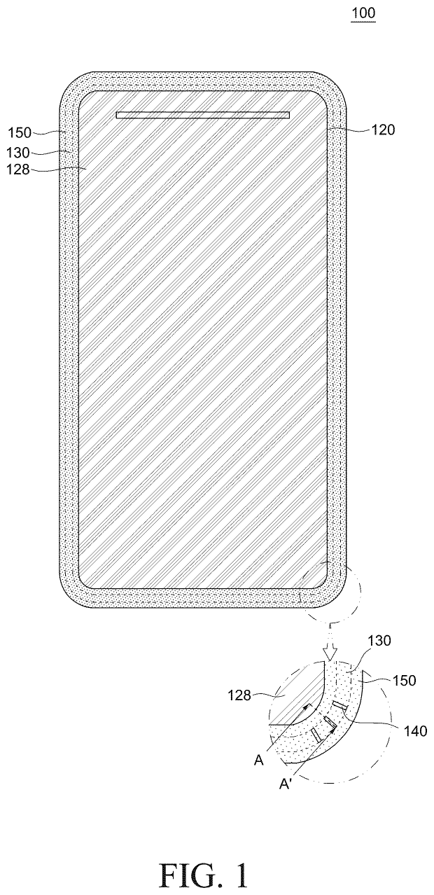

FIG. 1 is a rear view of a display device according to a first exemplary embodiment of the present disclosure.

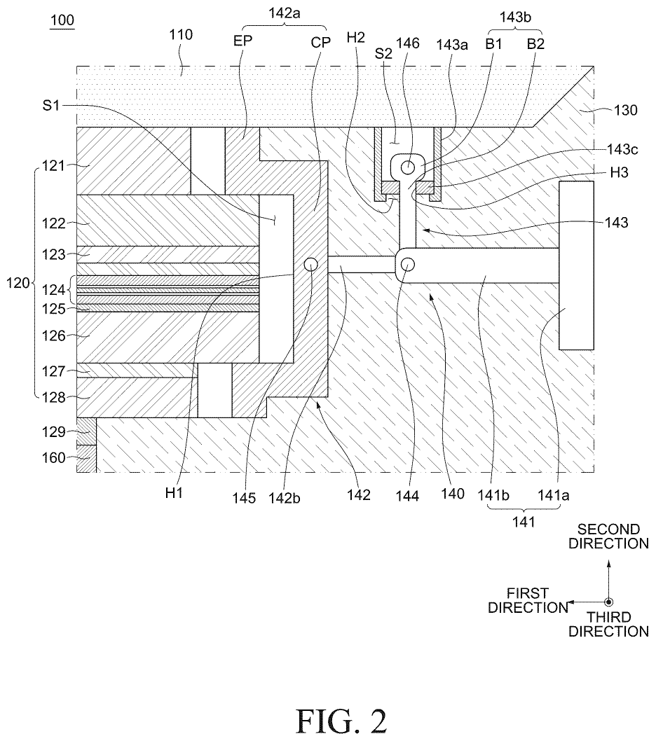

FIG. 2 is a cross-sectional view taken along A-A′ of FIG. 1.

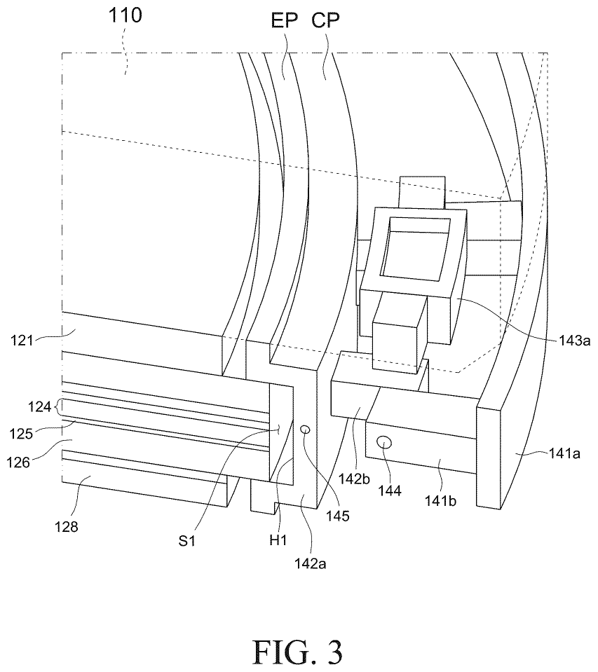

FIG. 3 is a partial enlarged perspective view of a display device of FIG. 2.

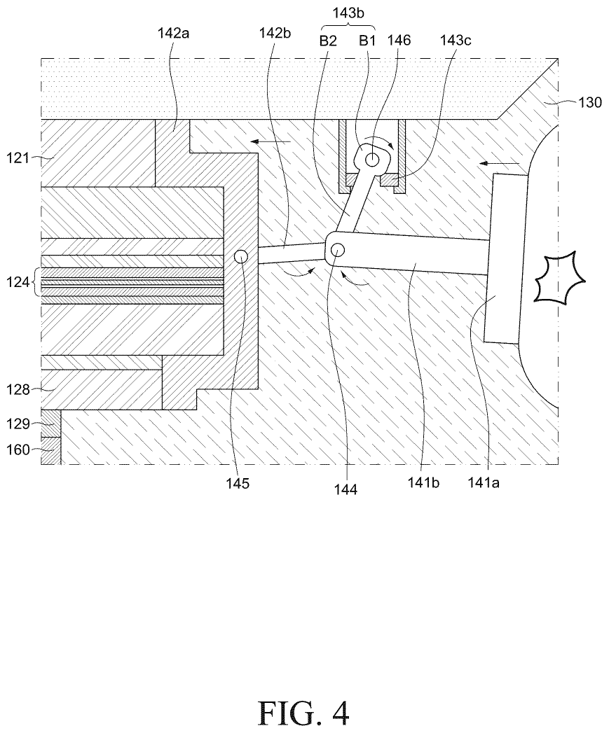

FIG. 4 is a view illustrating a state in which an external impact is generated, in a display device according to a first exemplary embodiment of the present disclosure.

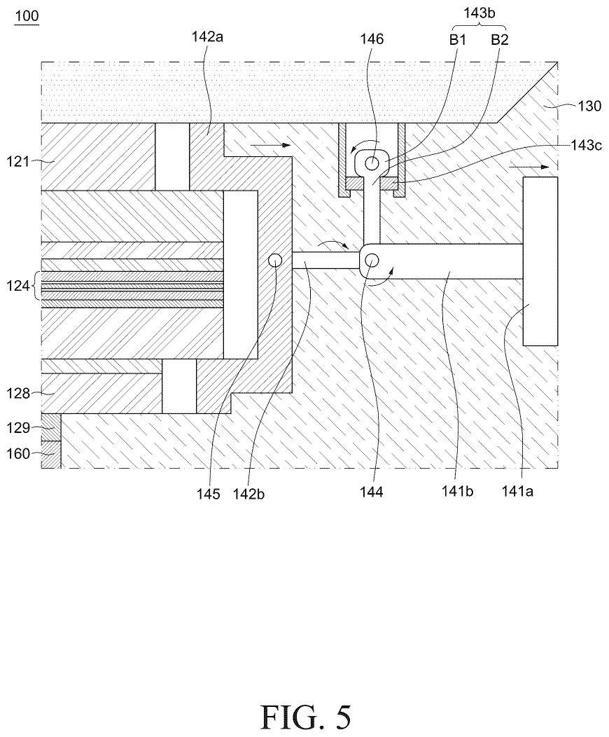

FIG. 5 is a view illustrating a state which returns to its original state after an external impact is generated, in a display device according to a first exemplary embodiment of the present disclosure.

FIGS. 2 and 3 are a cross-sectional view and a perspective view illustrating one side of a display device 100 of FIG. 1, for example, an upper corner portion. At this time, the upper side may refer to a portion in which a printed circuit board is disposed.

In FIGS. 2 to 5, for the convenience of description, a housing 150 is not illustrated.

First, referring to FIGS. 1 to 5, the display device 100 according to the exemplary embodiment of the present disclosure may include a cover window 110, a display panel 120, a molding member 130, and a link assembly 140. Further, the display device 100 according to the first exemplary embodiment of the present disclosure may further include a housing 150.

The cover window 110 may be a component which is exposed to the outer periphery of the display device 100 and protect the display device 100 from external impact or scratches. Further, the cover window 110 may protect the display device 100 from moisture permeating from the outside.

The cover window 110 may be formed of a glass or a plastic material having a flexibility, but is not limited thereto.

The display panel 120 may be disposed below the cover window 110.

For example, the display panel 120 may include an adhesive layer 121, a polarization plate 122, a first adhesive 123, a main panel 124, a second adhesive 125, a back plate 126, a third adhesive 127, and a metal plate 128.

The adhesive layer 121 may be disposed between the polarization plate 122 and the cover window 110.

The adhesive layer 121 may bond the cover window 110 and the polarization plate 122.

The adhesive layer 121 may be formed of a transparent material so that an image of the main panel 124 is visible. At this time, for example, the adhesive layer 121 may be formed of an optical clear adhesive (OCA), but is not limited thereto.

The polarization plate 122 may be disposed between the cover window 110 and the main panel 124. The polarization plate 122 may be disposed between the adhesive layer 121 attached to the cover window 110 and the first adhesive 123 attached to the main panel 124.

The polarization plate 122 may reduce reflection of external light which is incident to the main panel 124. Specifically, the main panel 124 may include various metal materials which are applied to a semiconductor element, a wiring line, and an organic light emitting diode. Therefore, the external light incident to the main panel 124 may be reflected from the metal material and the visibility of the display panel 120 may be reduced due to the reflection of the external light. In contrast, when the polarization plate 122 is disposed, the polarization plate 122 suppresses the reflection of the external light so that the outdoor visibility of the display panel 120 may be increased.

At this time, the first adhesive 123 is disposed between the polarization plate 122 and the main panel 124 to bond the polarization plate 122 and the main panel 124.

The first adhesive 123 may be formed of a transparent material so that an image of the main panel 124 may be visible. The first adhesive 123 may be formed of an optical clear adhesive (OCA), but is not limited thereto.

The main panel 124 is a panel for displaying images to a user.

In the main panel 124, a display element which displays images, a driving element which drives the display element, and wiring lines which transmit various signals to the display element and the driving element may be disposed.

The display element may be defined in different manners depending on the type of the main panel 124. If the main panel 124 is an organic light emitting panel, the display element may be an organic light emitting diode which includes an anode, an organic emission layer, and a cathode. If the main panel 124 is a liquid crystal display panel, the display element may be a liquid crystal display element.

Hereinafter, even though the description will be made by assuming that the main panel 124 is an organic light emitting panel, the main panel 124 is not limited to the organic light emitting panel.

The main panel 124 may include a substrate, a pixel unit, and an encapsulation layer.

The substrate is a base member which supports various components of the main panel 124 and may be configured by an insulating material. The substrate may be formed of a plastic material having flexibility. The substrate may be formed of a plastic material, such as polyimide (PI), but is not limited thereto.

The pixel unit may include a plurality of organic light emitting diodes and a circuit for driving the organic light emitting diodes.

The main panel 124 may be configured by a top emission type or a bottom emission type, depending on an emission direction of light which is emitted from the organic light emitting diode.

According to the top emission type, light emitted from the organic light emitting diode is emitted to the top of the substrate on which the organic light emitting diode is formed. In the case of the top emission type, a reflection layer may be formed below the anode to allow the light emitted from the organic light emitting diode to travel toward an upper portion of the substrate, that is, toward the cathode.

According to the bottom emission type, light emitted from the organic light emitting diode is emitted to a lower portion of the substrate on which the organic light emitting diode is formed. In the case of the bottom emission type, the anode may be formed only of a transparent conductive material and the cathode may be formed of the metal material having a high reflectance to allow the light emitted from the organic light emitting diode to travel below the substrate.

Hereinafter, the description will be made by assuming that the display device 100 according to the first exemplary embodiment of the present disclosure is a top emission type, but it is not limited thereto.

The encapsulation layer may be disposed so as to cover the pixel unit. The encapsulation layer may seal the organic light emitting diode of the pixel unit. The encapsulation layer may protect the organic light emitting diode of the pixel unit from moisture, oxygen, or impact of the outside. The encapsulation layer may be formed by alternately laminating a plurality of inorganic layers and a plurality of organic layers. For example, the inorganic layer may be formed of an inorganic material such as silicon nitride (SiNx), silicon oxide (SiOx), and aluminum oxide (AlOx) and the organic layer may be formed of epoxy or acrylic polymer, but they are not limited thereto.

The second adhesive 125 is disposed between the main panel 124 and the back plate 126 to bond the main panel 124 and the back plate 126. The second adhesive 125 may be formed of a pressure sensitive adhesive (PSA), but is not limited thereto.

The back plate 126 may support the main panel 124. When the substrate of the main panel 124 is formed of a plastic material such as polyimide, due to the flexible characteristic, a separate component for protecting the substrate may be necessary. Therefore, the back plate 126 for supporting the substrate may be disposed below the main panel 124.

The back plate 126 may include a plastic material. The back plate 126 may be formed of a plastic thin film formed of polyimide (PI), polyethylene naphthalate (PEN), polyethylene terephthalate (PET), or a combination of the polymers.

For example, the third adhesive 127 is disposed between the back plate 126 and the metal plate 128 to bond the back plate 126 and the metal plate 128. The third adhesive 127 may be formed of a pressure sensitive adhesive (PSA), but is not limited thereto.

The metal plate 128 may protect the components of the display device 100 from external impacts. Further, the metal plate 128 serves as a ground to suppress the static electricity entering the display device 100 or easily discharge residual charges accumulated in the display device 100 to the outside. The metal plate 128 may easily discharge heat generated in the display device 100 to the outside. The metal plate 128 may be formed of a metal material having excellent thermal conductivity, electrical conductivity, and mechanical rigidity. For example, the metal plate 128 may be configured by copper (Cu) or stainless steel (SUS), but is not limited thereto.

A foam member 160 may be disposed below the metal plate 128. The foam member 160 may function to block the resin from entering toward the display panel 120 before being cured during a process of injecting resin of the molding member 130.

For example, the fourth adhesive 129 is disposed between the foam member 160 and the metal plate 128 to bond the foam member 160 and the metal plate 128. For example, the fourth adhesive 129 may be formed of a pressure sensitive adhesive (PSA), but is not limited thereto.

The molding member 130 is disposed below the cover window 110 and may be spaced apart from a side portion of the display panel 120. The molding member 130 may seal the cover window 110, the display panel 120, and the link assembly 140. Further, the link assembly 140 may be movably installed in the molding member 130.

The molding member 130 may suppress the permeation of the moisture or oxygen into the display panel 120. The molding member 130 may protect components of the display device 100 and relieve impacts applied to the display panel 120.

At this time, for example, the molding member 130 may be formed of one or more materials of acrylic resin, epoxy resin, phenolic resin, polyamides resin, polyimides resin, unsaturated polyesters resin, polyphenylene resin, polyphenylenesulfide resin, and benzocyclobutene, but is not limited thereto.

Further, the molding member 130 may form a space S1 with the side portion of the display panel 120 spaced apart therefrom.

The space S1 may form a sealed structure.

Specifically, an upper portion of the space S1 may be shielded by the cover window 110, one side portion may be shielded by the display panel 120, and a lower portion and the other side portion may be shielded by the molding member 130. In the space S1, the second plate 142a may be movably disposed.

The link assembly 140 may absorb and disperse the external impact applied to the molding member 130.

The link assembly 140 may elastically support the molding member 130 in response to movement (that is, a deformation) of the molding member 130 toward the display panel 120 (that is, directed to the display panel 120).

For example, when an impact is applied to the molding member 130, the link assembly 140 may ensure an impact absorption time as much as the molding member moves toward the display panel 120 (that is, while moving toward the display panel 120). Further, for example, the external impact is not directly transmitted from the molding member 130 to the display panel 120 through the link assembly 140, but the link assembly 140 may provide a time for allowing the molding member 130 to absorb the impact.

The link assembly 140 may be provided at a corner of the display device 100. For example, the link assembly 140 may be provided at a lower corner of the display device 100. At least three link assemblies 140 may be provided at the corner (see FIG. 1), but the present disclosure is not limited to the number of link assemblies 140. For example, if a mobile display device is dropped on the ground, the corner is likely to receive the greatest impact. Accordingly, the link assembly 140 may be disposed at the corner of the display device 100 to effectively relieve the impact.

The link assembly 140 may include a first link unit 141, a second link unit 142, a third link unit 143, a first shaft 144, a second shaft 145, and a third shaft 146.

The first link unit 141 may be connected to an end portion of the molding member 130. Specifically, the first link unit 141 may be connected to the end portion of the molding member 130 with respect to a first direction (see FIG. 2). The first link unit 141 may move toward the display panel 120 in conjunction with deformation of the molding member 130.

The first link unit 141 may include a first plate 141a and a first rod 141b.

The first plate 141a absorbs (or disperses) the external impact (and a pressure) applied to the molding member 130. The first plate 141a may be disposed on an end portion of the molding member 130. The first plate 141a may extend in a direction (hereinafter, referred to as a second direction) perpendicular to the first direction (see FIG. 2).

The first plate 141a may include an elastic material. For example, the first plate 141a may be configured by rubber formed of ethylene propylene diene monomer (EPDM), polyurethane (PU), or a combination of the polymers, but the present disclosure is not limited thereto.

When the molding member 130 is deformed due to the external impact, the first plate 141a moves toward the display panel 120 together with the molding member 130 to absorb (and disperse) an impact energy applied to the molding member 130.

The first rod 141b may be movably disposed in the molding member 130. For example, one side of the first rod 141b may be fixed to the first plate 141a and the other side may be rotatably coupled to the first shaft 144. The first rod 141b may extend along the first direction.

For example, the first rod 141b may move toward the display panel 120 in conjunction with movement of the first plate 141a and rotate (that is, pivot) a third rod 143b toward the display panel 120.

Further, a part of the second link unit 142 may be disposed in the sealed space S1 between the molding member 130 and a side portion of the display panel 120 and the other part may be disposed in the molding member 130. The second link unit 142 may be rotatably connected to the first link unit 141 and the third link unit 143 through the first shaft 144.

The second link unit 142 may include a second plate 142a and a second rod 142b.

The second plate 142a may be disposed to be horizontally movable in the sealed space S1. The second plate 142a may be rotatably connected to the second rod 142b by the second shaft 145.

The second plate 142a may include a center plate CP and an end plate EP.

The center plate CP may be disposed in the center of the space S1 with respect to the second direction. The center plate CP may be rotatably connected to the second rod 142b through the second shaft 145.

Further, the center plate CP may include a groove H1 which is inwardly recessed at one side opposite the main panel 124. For example, the main panel 124 may be inserted into the groove H1 and an inner surface of the center plate CP which forms the groove H1 may be in contact with a side surface of the main panel 124. As another example, in the groove H1, the polarization plate 122, the first adhesive 123, the main panel 124, the second adhesive 125, and the back plate 126 may be inserted.

Further, end plate EP may be disposed in both side portions of the space S1 with respect to the second direction. The end plate EP may extend along the second direction from both sides of the center plate CP. The end plate EP may be in contact with a side surface of the adhesive layer 121 and a side surface of the metal plate 128 (and the third adhesive 127).

The second plate 142a may be in contact with a side portion of the display panel 120 while moving toward the display panel 120 by the first link unit 141. The second plate 142a is located between the display panel 120 and the molding member 130 to serve as a buffer material. Accordingly, the molding member 130 is suppressed from being in direct contact with the display panel 120 to suppress the crack generated in the display panel 120 due to the molding member 130.

Further, the second plate 142a may move toward the side portion of the display panel 120 to be in contact therewith in conjunction with operations of the first link unit 141 and the third link unit 143. At this time, the second plate 142a may be affected by resistance caused by the fluid, in the sealed space S1 between the molding member 130 and the side portion of the display panel 120. The resistance generated by the fluid while the second plate 142a moves dissipates the impact energy transmitted from the first link unit 141 so that the impact to be transmitted to the display panel 120 through the second plate 142a may be partially absorbed.

The second rod 142b may be movably disposed in the molding member 130. One side of the second rod 142b may be rotatably connected to the first link unit 141 and the third link unit 143 through the first shaft 144. The other side of the second rod 142b may be rotatably connected to the second plate 142a by the second shaft 145. The second rod 142b may extend along the first direction.

The second rod 142b may move toward the display panel 120 in conjunction with movement of the first rod 141b and pressurize the second plate 142a toward the display panel 120. For example, the second rod 142b may be rotatably supported to the third rod 143b through the first shaft 144 to form a gradient placement in which one side (that is, a part connected to the third rod 143b) of the second rod 142b is located higher and the other side (that is, a part connected to the first rod 141b) is located lower in conjunction with a pivot operation of the third rod 143b. As described above, the second rod 142b is applied with the resistance by the molding member 130 while forming the gradient placement and the impact energy transmitted from the first link unit 141 may partially dissipate by the resistance of the molding member 130.

The third link unit 143 is connected to the first link unit 141 and the second link unit 142 to supply resilience to the first link unit 141 and the second link unit 142. The third link unit 143 may be rotatably connected to the first link unit 141 and the second link unit 142 through the first shaft 144.

For example, the third link unit 143 may include a link housing 143a, a third rod 143b, and a support bush 143c.

The link housing 143a may be attached to the cover window 110.

A side portion of the link housing 143a may be supported by the molding member 130.

The link housing 143a may include an accommodation space S2 therein. In the accommodation space S2, the support bush 143c and the third rod 143b may be disposed.

The link housing 143a may include a through hole H2 which communicates with the accommodation space S2 therebelow. The third shaft 146 may be located in the accommodation space S2 of the link housing 143a and the third rod 143b may be disposed in the through hole H2.

Even though it is not illustrated, an inner surface of the link housing 143a which forms the through hole H2 may be upwardly inclined toward an upper side from a lower side. The pivoting third rod 143b may be in contact with the upwardly inclined inner surface of the through hole H2 to be supported.

The third rod 143b may be rotatably installed in the link housing 143a at a predetermined angle range and may be rotatably connected to the first link unit 141. The third rod 143b may pivot in a state in which a rotary shaft (that is, a rotary shaft by the third shaft 146) is formed in the link housing 143a.

The third rod 143b is rotatably coupled to the third shaft 146 and passes through the through hole H2 to protrude downwardly from the link housing 143a and to be elastically supported by the support bush 143c. The third rod 143b may rotate (that is, pivot) by the first link unit 141.

Hereinafter, an example that a pivoting direction of the third rod 143b by the first link unit 141 is a clockwise direction will be described and an example that a direction that the third rod 143b returns to its original position by the support bush 143c is a counterclockwise direction will be described.

The third rod 143b may include a first bar B1 and a second bar B2.

The first bar B1 may be disposed in the accommodation space S2 and may be rotatably supported to the third shaft 146. A lower edge portion of the first bar B1 may be formed as a rounded surface. When the third rod 143b pivots, a rounded surface of the first bar B1 may be in contact with an upper portion of the support bush 143c.

The second bar B2 may be formed to extend downwardly from the first bar B1. A part of the second bar B2 may be located in the accommodation space S2 and the through hole H2 and the other part of the second bar B2 protrudes outwardly from the link housing 143a to be disposed in the molding member 130.

An upper portion of the second bar B2 is inserted into an insertion hole H3 of the support bush 143c and may be elastically supported on an inner surface of the support bush 143c which forms the insertion hole H3. A lower portion of the second bar B2 may be rotatably coupled to the first rod 141b by the first shaft 144.

The third rod 143b may pivot toward the display panel 120 by the impact energy transmitted from the first link unit 141. The third rod 143b may be elastically supported by the support bush 143c while pivoting and the impact energy may be transformed to the thermal energy by the elastic force of the support bush 143c to dissipate.

At least a part of the support bush 143c may be disposed between the link housing 143a and the third rod 143b and elastically support the third rod 143b.

Both sides of the support bush 143c may be supported on the inner surface of the link housing 143a which forms the accommodation space S2 and a part of a lower portion may be supported by the inner surface of the link housing 143a which forms the through hole H2.

An insertion hole H3 which passes therethrough along the second direction may be formed in the center portion of the support bush 143c.

The second bar B2 of the third rod 143b may be inserted into the insertion hole H3. In a state in which the third rod 143b is inserted into the insertion hole H3, an outer surface of the second bar B2 is in contact with the inner surface of the support bush 143c which forms the insertion hole H3. By doing this, the support bush 143c elastically supports the third rod 143b.

Further, a diameter of the insertion hole H3 may be smaller than a diameter of the through hole H2. The diameter of the insertion hole H3 is formed to be smaller than the diameter of the through hole H2 so that in a state in which the third rod 143b is inserted into the insertion hole H3 to be supported by the support bush 143c, the inside of the through hole H2 may pivot.

The support bush 143c may be formed with an elastic material so as to elastically support the third rod 143b. The support bush 143c may include an elastic material. For example, the support bush 143c may be configured by rubber formed of ethylene propylene diene monomer (EPDM), polyurethane (PU), or a combination of the polymers, but the present disclosure is not limited thereto.

The support bush 143c may be formed as a circular plate with a penetrated center portion (that is, the insertion hole H3 is formed). For example, the support bush 143c may be formed in a disk shape.

Further, the diameter of the support bush 143c may be equal to or larger than the diameter of the accommodation space S2. By doing this, the support bush 143c may be coupled to the link housing 143a to be forcibly fitted and may be more firmly coupled to the link housing 143a.

The support bush 143c may be elastically deformed while elastically supporting the pivoting third rod 143b and dissipate a part of the impact energy transmitted from the third rod 143b while being elastically deformed. Further, the support bush 143c may return the third rod 143b to its original position by means of the elastic force generated while being elastically deformed.

The first shaft 144 may be disposed in the molding member 130.

The first shaft 144 extends along a third direction and may be rotatably coupled to a lower portion of the third rod 143b. Further, the first shaft 144 may rotatably connect the first rod 141b, the third rod 143b, and the second rod 142b with each other.

The second shaft 145 may extend along the third direction and rotatably connect the second plate 142a and the second rod 142b with each other.

The third shaft 146 may be disposed in the link housing 143a.

The third shaft 146 may extend along a direction (that is, the third direction, see FIG. 2) horizontally perpendicular to the first direction. Both side portions of the third shaft 146 may be rotatably coupled to the link housing 143a.

In the meantime, the housing 150 may cover the side portion of the molding member 130.

The housing 150 may be disposed on a side surface of the cover window 110 and a side surface and a bottom surface of the molding member 130. The housing 150 covers the cover window 110 and the molding member 130 to protect the cover window 110 and the molding member 130.

An inner surface of the housing 150 may be bonded to the molding member 130. A part of the inner surface of the housing 150 may be bonded to the molding member 130. The housing 150 is bonded to the molding member 130 to cover a side surface and a bottom surface of the molding member 130. A housing adhesive layer (not illustrated) may be disposed between the inner surface of the housing 150 and the molding member 130. The housing adhesive layer may be disposed between the inner surface of the housing 150 and the molding member 130 to bond the inner surface of the housing 150 and the molding member 130, but the present disclosure is not limited thereto.

The housing 150 may be formed of a material having a predetermined rigidity to protect the side surfaces of the cover window 110 and the molding member 130. For example, the housing 150 may be formed of a plastic formed by any one of polyimide (PI), polyethylene naphthalate (PEN), polyethylene terephthalate (PET) and a combination of the polymers or a metal such as copper (Cu) or stainless steel (SUS), but is not limited thereto.

Hereinafter, a series of processes of absorbing an impact applied to the molding member 130 by the link assembly 140 and returning to its original position after absorbing the impact will be described.

First, referring to FIGS. 2 and 4, when the impact is applied to the molding member 130, the first plate 141a and the first rod 141b may move toward the display panel 120. The first rod 141b may transmit an impact energy to the second rod 142b and the second plate 142a through the first shaft 144 and the first plate 141a and the first rod 141b and the second rod 142b and the second plate 142a may move toward the display panel 120 together with the molding member 130. Further, as the first plate 141a and the first rod 141b and the second rod 142b and the second plate 142a move together with the molding member 130, an impact absorption time may be ensured to delay the transmission of the external impact energy to the display panel 120.

Therefore, more time for allowing the molding member 130 to absorb the impact energy is ensured to absorb and dissipate the impact energy. Further, the link assembly 140 may absorb and dissipate the impact energy simultaneously with the process of absorbing the impact energy by the molding member 130.

First, the second plate 142a receives the impact energy through the first plate 141a, the first rod 141b, and the second rod 142b to move to the first direction in the space S1. At this time, the second plate 142a may receive the resistance caused by the fluid in the sealed space S1. That is, the resistance may be generated by the air brake phenomenon while the second plate 142a moves. The resistance generated by the fluid while the second plate 142a moves may dissipate the impact energy transmitted from the first link unit 141 so that the impact to be transmitted to the display panel 120 through the second plate 142a may be cancelled.

Further, the third link unit 143 may receive the impact energy through the first plate 141a and the first rod 141b. The third rod 143b may pivot along the clockwise direction through the first rod 141b and the first shaft 144. The third rod 143b may be elastically supported to the support bush 143c during the pivoting and the impact energy may be transformed to the thermal energy by the elastic force of the support bush 143c to dissipate.

As described above, the impact energy applied to the molding member 130 may be absorbed and dissipate by a factor which increases the impact absorption time of the molding member 130 while the link assembly 140 moves together with the molding member 130, a resistance factor generated while the second plate 142a moves in the space S1, and the elasticity factor generated while the support bush 143c is elastically deformed by the third rod 143b.

Further, the external impact energy may be absorbed and dissipate also with its elastic force of each of the first rod 141b, the second rod 142b, and the third rod 143b.

Next, referring to FIGS. 4 and 5, the link assembly 140 may return to its original position which is a position before the link assembly 140 moves, by the elastic resilience generated while the support bush 143c is elastically deformed.

First, the third rod 143b may pivot along the counterclockwise direction by the elastic resilience of the support bush 143c. The second rod 142b and the second plate 142a may move away from the display panel 120 (that is, an opposite direction of the first direction) in conjunction with the pivoting of the third rod 143b. The second rod 142b moves away from the display panel 120 to push the first rod 141b and the first plate 141a so that the first plate 141a may return to its original position. The molding member 130 may also return to its original position (that is, a position before the impact occurs) while the first plate 141a returns to its original position.

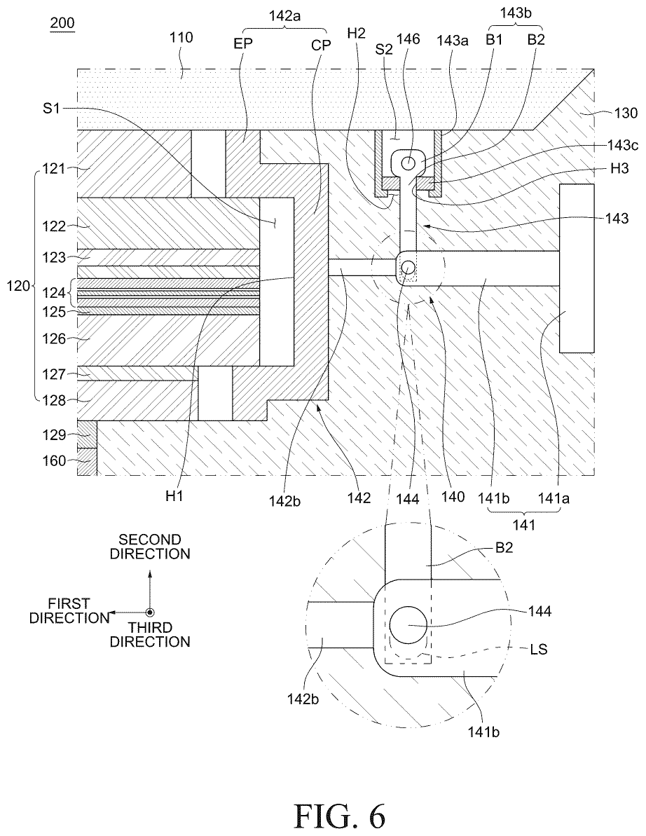

FIG. 6 is a cross-sectional view of a display device according to a second exemplary embodiment of the present disclosure.

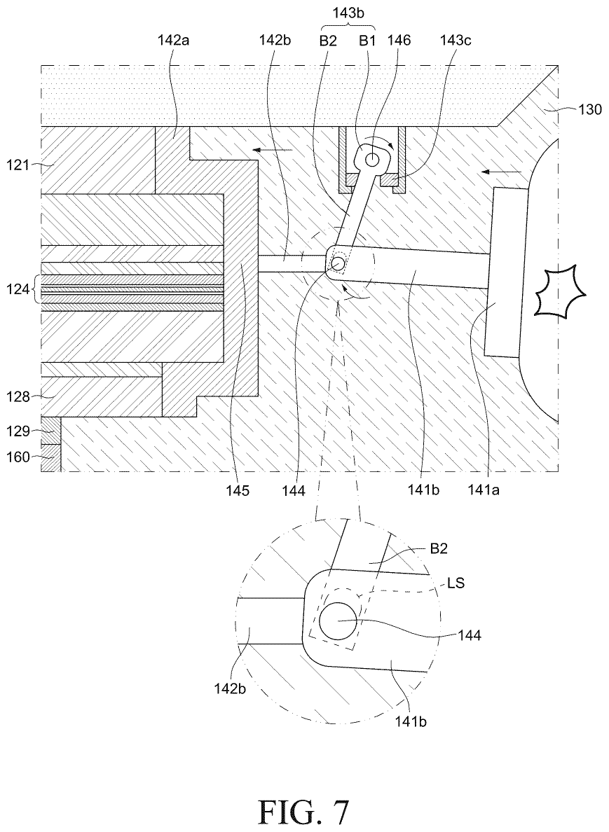

FIG. 7 is a view illustrating a state in which an external impact is generated, in a display device according to a second exemplary embodiment of the present disclosure.

A display device 200 of a second exemplary embodiment of FIGS. 6 and 7 is substantially the same as the above-described display device 100 of the first exemplary embodiment of FIGS. 1 to 5 except that a link slit LS is formed in the third rod 143b and a second shaft 145 is not provided, so that a redundant description will be omitted. Further, the same configuration will be denoted with the same reference numeral. The description for the same reference numeral may refer to FIGS. 1 to 5.

Referring to FIGS. 6 and 7, the display device 200 according to the second exemplary embodiment of the present disclosure may further include a link slit LS.

For example, the link slit LS may be formed to pass through the third rod 143b in the third direction at a lower end of the third rod 143b (that is, the second bar B2). The link slit LS may be formed at the lower end of the third rod 143b with a predetermined length.

The first shaft 144 may be inserted into the link slit LS. The first shaft 144 may move along the link slit LS formed with a predetermined length. For example, when the third rod 143b is disposed to be parallel to the second direction, the first shaft 144 may be disposed in a relatively lower side in the link slit LS. In contrast, when the third rod 143b rotates along the clockwise direction, the first shaft 144 may be disposed in a relatively upper side of the link slit LS.

When the impact is applied to the molding member 130, in the display device 200 of the second exemplary embodiment, the first link unit 141 may move toward the display panel 120. The third rod 143b pivots in the clockwise direction in conjunction with the movement of the first link unit 141, and the second rod 142b and the second plate 142a may horizontally move along the first direction in conjunction with the pivoting of the third rod 143b. At this time, a position of the first shaft 144 may be changed from the lower side of the link slit LS to the upper side of the link slit LS while moving along the link slit LS. As the first shaft 144 moves along the link slit LS, an impact absorption time of the molding member 130 is increased and the molding member 130 may absorb more external impact energy as much as the increased time. It means that the impact energy absorbed by the molding member 130 before the external impact energy is transmitted from the molding member 130 to the display panel 120 is increased.

In the display device 200 according to the second exemplary embodiment of the present disclosure, the second rod 142b horizontally moves along the first direction through the link slit LS so that the second plate 142a may receive more resistance of the fluid in the sealed space S1. The impact absorption time is increased by the resistance of the fluid so that the impact energy absorbed by the molding member 130 may be increased.

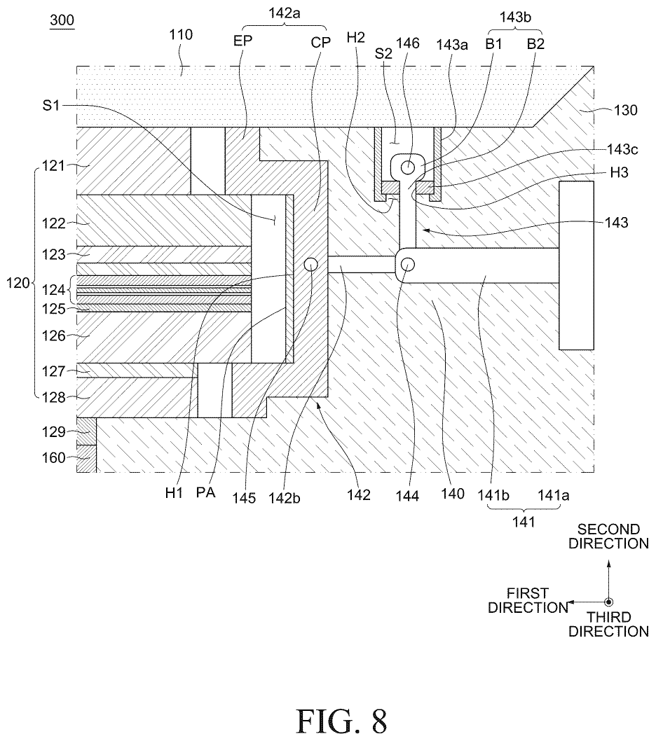

FIG. 8 is a cross-sectional view of a display device according to a third exemplary embodiment of the present disclosure.

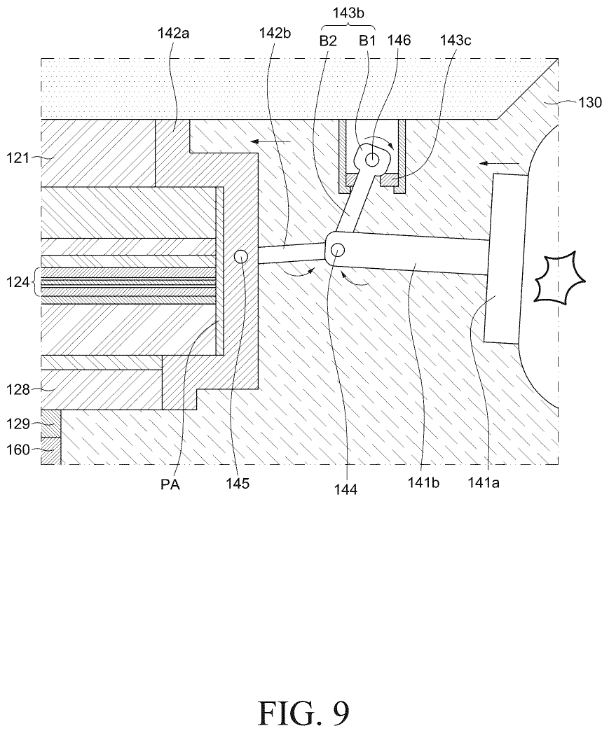

FIG. 9 is a view illustrating a state in which an external impact is generated, in a display device according to a third exemplary embodiment of the present disclosure.

A display device 300 of a third exemplary embodiment of FIGS. 8 and 9 is substantially the same as the above-described display device 100 of the first exemplary embodiment of FIGS. 1 to 5 except that a second link unit 142 further includes a pad PA, so that a redundant description will be omitted. The same configuration will be denoted by the same reference numeral. The description for the same reference numeral may refer to FIGS. 1 to 7.

Referring to FIGS. 8 and 9, a display device 300 according to a third exemplary embodiment of the present disclosure may further include a pad PA.

The pad PA may be disposed in the groove H1 of the second plate 142a to be opposite to the display panel 120. The pad PA may be disposed in the center plate CP.

For example, a length of the pad PA of the second direction may be formed to be the same as a height by which the polarization plate 122, the main panel 124, and the back plate 126 are laminated.

The pad PA may be formed of an elastic material. The pad PA may be configured by rubber formed of ethylene propylene diene monomer (EPDM), polyurethane (PU), or a combination of the polymers, but the present disclosure is not limited thereto.

When the impact is applied to the molding member 130, in the display device 300 of the third exemplary embodiment, the first link unit 141 may move toward the display panel 120. The second link unit 142 may move toward the display panel 120 in conjunction with the operations of the first link unit 141 and the third link unit 143. The pad PA attached to the second plate 142a may be in contact with the display panel 120. The pad PA serves as a buffer material between the display panel 120 and the second link unit 142 to absorb the impact energy to be transmitted to the display panel 120.

The exemplary embodiments of the present disclosure can also be described as follows:

According to an aspect of the present disclosure, there is provided a display device. The display device includes a cover window a display panel disposed below the cover window, a molding member disposed on a side surface of the display panel and a link assembly which is at least partially disposed between a side of the display panel and the molding member to absorb an impact applied to the display panel.

The link assembly may includes a first link unit which is coupled to the molding member so as to expose at least a part to the outside of the molding member, a second link unit which is connected to the first link unit and is disposed between the side of the display panel and the molding member and a third link unit which is connected to the first link unit and the second link unit and supplies resilience to the first link unit and the second link unit.

The first link unit may include a first plate which is exposed to the outside of the molding member to receive external impact and a first rod which extends from an inner surface of the first plate and is rotatably connected to the second link unit and the third link unit.

The second link unit may includes a second plate which is movably disposed between one side of the display panel and the molding member and a second rod having one end which is rotatably connected to the second plate and the other end which is rotatably connected to the first link unit and the third link unit.

The third link unit may includes a link housing, a third rod having one end which is pivotably disposed in the link housing and the other end which is rotatably connected to the first rod and the second rod and a support bush which is disposed between the link housing and the third rod to supply resilience to the third rod.

The link assembly may further include a first shaft which rotatably connects the first link unit, the second link unit, and the third link unit.

The link assembly may further include a second shaft which rotatably connects the second rod and the second plate.

The link assembly may further include a third shaft which rotatably supports the third rod.

The support bush may surround the third rod and may be made of any one material of ethylene propylene diene monomer (EPDM) and polyurethane (PU).

The support bush may have a disk shape.

The link housing may be attached to the cover window and may include a through hole through which the third rod passes.

The support bush may include an insertion hole into which the third rod is inserted and diameter of the insertion hole may be smaller than a diameter of the through hole.

The display panel may include a main panel, an adhesive layer which is disposed between the main panel and the cover window and is shorter than the main panel and a metal plate which is disposed below the main panel and is shorter than the main panel, and the second plate may have a groove into which the main panel is inserted.

The second plate may include a center plate which is contactable to a side portion of the main panel and has the groove and an end plate which extends to both sides of the center plate and is contactable to the adhesive layer and the metal plate.

The third rod may include a link slit in which the first shaft is movably disposed at a lower end.

The second link unit may include a pad which is disposed in a groove of the second plate to be opposite to the display panel.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a cover window;
a display panel disposed below the cover window;
a molding member disposed on a side surface of the display panel; and
a link assembly at least partially disposed between a side of the display panel and the molding member to absorb an impact applied to the display panel.

2. The display device according to claim 1, wherein the link assembly includes:
a first link unit coupled to the molding member, with at least a part exposed outside the molding member;
a second link unit connected to the first link unit and disposed between the side of the display panel and the molding member; and
a third link unit connected to the first link unit and the second link unit and configured to supply resilience to the first link unit and the second link unit.

3. The display device according to claim 2, wherein the first link unit includes:
a first plate exposed to the outside of the molding member to receive external impact; and
a first rod extending from an inner surface of the first plate and rotatably connected to the second link unit and the third link unit.

4. The display device according to claim 2, wherein the second link unit includes:
a second plate movably disposed between one side of the display panel and the molding member; and
a second rod with one end rotatably connected to the second plate and the other end rotatably connected to the first link unit and the third link unit.

5. The display device according to claim 4, wherein the display panel includes:
a main panel;
an adhesive layer disposed between the main panel and the cover window, smaller in size than the main panel; and
a metal plate disposed below the main panel, smaller in size than the main panel, and
wherein the second plate has a groove into which the main panel is inserted.

6. The display device according to claim 5, wherein the second plate includes:
a center plate contactable with a side portion of the main panel and having the groove; and
an end plate extending to both sides of the center plate and contactable with the adhesive layer and the metal plate.

7. The display device according to claim 5, wherein the second link unit includes a pad disposed in a groove of the second plate facing the display panel.

8. The display device according to claim 2, wherein the third link unit includes:
a link housing;
a third rod with one end pivotably disposed in the link housing and the other end rotatably connected to the first rod and the second rod; and
a support bush disposed between the link housing and the third rod to supply resilience to the third rod.

9. The display device according to claim 8, wherein the link assembly further includes a first shaft rotatably connecting the first link unit, the second link unit, and the third link unit.

10. The display device according to claim 9, wherein the link assembly further includes a second shaft rotatably connecting the second rod and the second plate.

11. The display device according to claim 9, wherein the third rod includes a link slit at a lower end portion in which the first shaft is movably disposed.

12. The display device according to claim 8, wherein the link assembly further includes a third shaft rotatably supporting the third rod.

13. The display device according to claim 8, wherein the support bush surrounds the third rod and is made of any one of ethylene propylene diene monomer (EPDM) and polyurethane (PU).

14. The display device according to claim 8, wherein the support bush has a disk shape.

15. The display device according to claim 8, wherein the link housing is attached to the cover window and includes a through hole through which the third rod passes.

16. The display device according to claim 15, wherein the support bush includes an insertion hole into which the third rod is inserted, and
wherein a diameter of the insertion hole is smaller than that of the through hole.
